(19) United States
(12) Patent Application Publication
(10) Pub. No.: US 2008/0010575 A1
(43) Pub. Date: Jan. 10, 2008

(54) Semiconductor device

(76) Inventor: Tokushi Yamaguchi, Tokyo (JP)

Correspondence Address: MCDERMOTT WILL & EMERY LLP, 600 13TH STREET, NW, WASHINGTON, DC, 20005-3096, US

(21) Appl. No.: 11/808,160

(22) Filed: Jun. 7, 2007

(30) Foreign Application Priority Data
Jun. 7, 2006 (JP) P. 2006-158377

(51) Int. Cl. G01R 31/28

(52) U.S. Cl. 714/734

(57) ABSTRACT

The semiconductor device is equipped with a logic circuit such as a memory; a self test circuit for self-testing the logic circuit; a critical path defined up to the logic circuit; a test path defined from the self test circuit up to the logic circuit; a delay circuit provided on the test path, to which a delay value equivalent to a delay value of the critical path is set; and a selecting/outputting circuit for selecting any one of a signal inputted via the critical path and another signal inputted via the test path and for outputting the selected signal.

### BACKGROUND OF THE INVENTION

1. Field of the Invention

The present invention is related to a semiconductor device capable of performing screening inspections in a higher efficiency.

2. Description of the Related Art

Since semiconductor devices have been highly integrated and operated in high speeds, narrowing of widths as to transistors and wiring lines has been rapidly progressed. However, if very fine techniques of manufacturing processes are progressed, then failures may easily occur due to the following causes, namely, fluctuations of processes, and slight defects occurred during manufacturing operations. As a consequence, BIST (Built-In Self Test) has been utilized as test methods capable of guaranteeing actual operations.

For instance, an LSI equipped with a memory and pathes and having a self test function contains thereon a memory BIST circuit. As represented in FIG. 6, when the LSI performs a screening inspection due to the self test function, the memory BIST circuit executes a timing analysis (STA: Static Timing Analysis) for a critical path defined up to the memory (step S11). Next, the memory BIST circuit produces a test pattern (step S13). Subsequently, the memory BIST circuit performs a delay failure test of the critical path through which a signal is transferred when the LSI is operated under normal operation (step S15). Finally, the memory BIST circuit performs a failure test of the memory (step S17). It should be understood that in the failure test of the memory, the memory BIST circuit detects a delay failure, a degeneration failure, an open failure, a bridge failure, and so on.

Patent Publication 1: JP-A-2000-99557

As previously described, in the screening inspections executed by the LSI, at least 2 sorts of failure tests are carried out, namely, the delay failure test for the critical path and the failure test for the memory are performed by the LSI. Since the test pattern is generated every time the failure test is performed, at least two test patterns are generated in the relevant screening inspection. As a consequence, steps and times for generating these two test patterns are necessarily required. Also, a pattern memory for storing thereinto test patterns must require a storage capacity capable of storing thereinto at least two test patterns. However, when efficiencies of screening inspections are considered, it is desirable that a total number of test steps is smaller, it is preferable that a total test time is shorter, and also, it is desirable that a storage capacity of a pattern memory is lower.

### SUMMARY OF THE INVENTION

An object of the present invention is to provide a semiconductor device capable of performing screening inspections in a higher efficiency.

The present invention is to provide a semiconductor device featured by such a semiconductor device having a self test function, comprising: a failure detecting circuit for detecting a failure of a logic circuit by employing a test pattern; a critical path defined up to the logic circuit; a test path defined from the failure detecting circuit up to the logic circuit; a delay circuit provided on the test path, to which a delay value equivalent to a delay value of the critical path is set; and a selecting/outputting circuit for selecting any one of a signal inputted via the critical path and another signal inputted via the test path and for outputting the selected signal; in which the selecting/outputting circuit outputs the signal entered via the critical path when the semiconductor device is operated under normal operation, and outputs the signal entered via the test path and the delay circuit when the semiconductor device is operated under self test operation.

In the above-described semiconductor device, the delay value of the critical path is obtained by a timing analysis.

In the above-described semiconductor device, the delay value set to the delay circuit is variable.

In the above-described semiconductor device, the delay circuit includes a storage unit for storing thereinto the set delay value.

In the above-described semiconductor device, the semiconductor device is further comprised of: an output terminal for switching current levels of the signals outputted from the selecting/outputting unit.

In the above-described semiconductor device, the logic circuit is a memory.

In the above-described semiconductor device, the logic circuit is provided inside the semiconductor device.

In the above-described semiconductor device, the failure of the logic circuit detected by the failure detecting circuit contains a delay failure.

In accordance with the semiconductor device related to the present invention, the screening inspections can be carried out in the higher efficiency.

### BRIEF DESCRIPTION OF THE DRAWINGS

FIG. 1 is a block diagram for showing a structure of a semiconductor device according to a first embodiment mode of the present invention.

FIG. 2 is a flow chart for describing operations when a screening inspection of the semiconductor device of the first embodiment mode is carried out.

FIG. 3 is a block diagram for indicating an arrangement of a semiconductor device applied to an externally-provided memory.

FIG. 4 is a block diagram for showing a structure of a semiconductor device according to a second embodiment mode of the present invention.

FIG. 5 is a block diagram for showing a structure of a semiconductor device according to a third embodiment mode of the present invention.

FIG. 6 is the flow chart for describing the operations when the screening inspection of the conventional semiconductor device is carried out.

### DESCRIPTION OF THE PREFERRED EMBODIMENTS

Referring now to drawings, embodiment modes of the present invention will be described.

### First Embodiment Mode

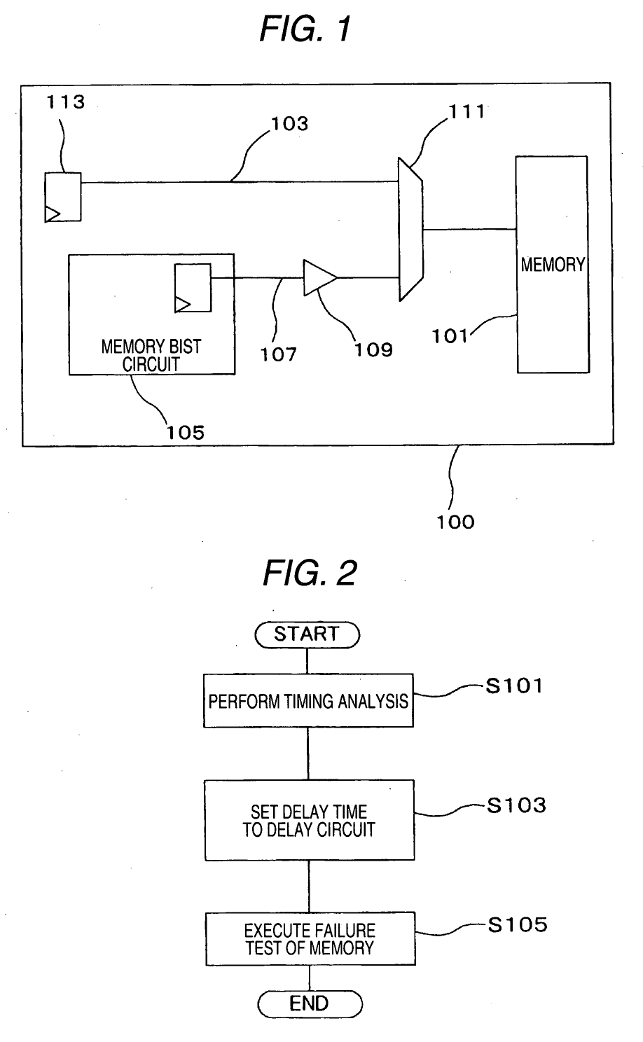

FIG. 1 is a block diagram for representing a structure of a semiconductor device 100 according to a first embodiment mode of the present invention. As indicated in FIG. 1, the semiconductor device 100 of the first embodiment mode is an LSI (Large-Scaled Integration) equipped with a memory 101, a normal operation path 103, a memory BIST (Built-In Self Test) circuit 105, a test operation path 107, a delay circuit 109, and a selector 111. The LSI has a function for self-testing the memory 101.

The normal operation path 103 corresponds to a critical path defined from a flip-flop (FF) 113 of a data processing unit (not shown) to the memory 101 within the semiconductor device 100. The memory BIST circuit 105 performs a timing analysis (STA) of the normal operation path 103, produces a test pattern, and performs a failure test for the memory 101 by employing the produced test pattern. The test operation path 107 corresponds to a path defined from the memory BIST circuit 105 to the memory 101, and contains the delay circuit 109 on the own test operation path 107. The delay circuit 109 is a buffer having such a delay value which is equivalent to a delay value of the normal operation path 103. It should be understood that the delay value of the normal operation path 103 is obtained by the timing analysis performed by the memory BIST circuit 105.

The selector 111 outputs any one of a signal entered via the normal operation path 103, and another signal entered via the test operation path 107 to the memory 101. The selector 111 outputs the signal inputted via the normal operation path 103 during normal operation of the semiconductor device 100, and outputs the signal entered via the test operation path 107 during test operation of the semiconductor device 100.

FIG. 2 is a flow chart for describing operations when a screening inspection of the semiconductor device 100 is carried out. As shown in FIG. 2, the memory BIST circuit 105 executes a timing analysis of the normal operation path 103 so as to analyze a delay value of the normal operation path 103 (step S101). Next, the memory BIST circuit 105 sets the delay value acquired in the step S101 to the delay circuit 109 (step S103). Next, the memory BIST circuit 105 executes a failure test of the memory 101 in a similar manner to that of the step S17 shown in FIG. 6 (step S105). It should be noted that in the memory failure test, the memory BIST circuit 105 detects a delay failure, a degeneration failure, an open failure, a bridge failure, and so on.

As previously described, in accordance with the semiconductor device 100 of the first embodiment mode, the delay circuit 109 having the delay value equivalent to the delay value of the normal operation path 103 is provided on the test operation path 107. As a result, the screening inspection of the semiconductor device 100 can be carried out without performing the delay failure test of the normal operation path 103.

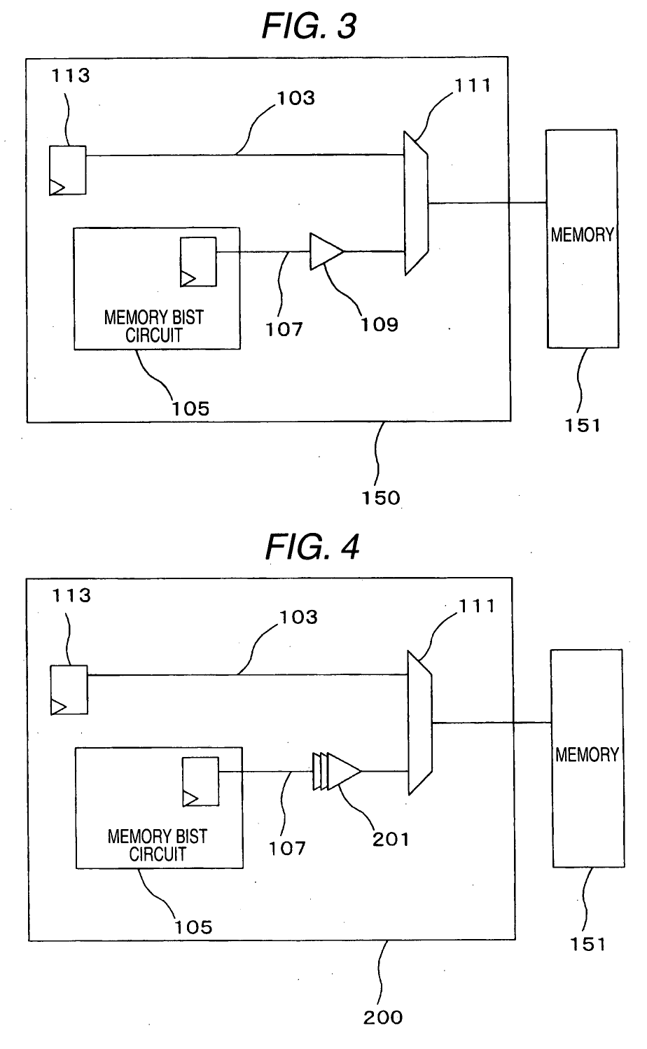

It should be understood that although the memory 101 has been provided inside the semiconductor device 100 in the above description, the memory 101 may be alternatively provided outside a semiconductor 150 as represent in FIG. 3. Even in this alternative case, a failure test of an external memory 151 is merely carried out without performing a delay failure test of the normal operation path 103, so that a screening inspection of the semiconductor device 150 may be carried out.

### Second Embodiment Mode

FIG. 4 is a block diagram or indicating a structure of a semiconductor device 200 according to a second embodiment mode of the present invention. The semiconductor device 200 of this second embodiment mode has the following different points from the semiconductor device 100 as described in the first embodiment mode. That is, in the second embodiment mode, a memory 151 is provided outside the semiconductor device 200, and a delay value set to the delay circuit 201 is variable. Other points than the above-described points are similar to those of the first embodiment mode, and the same reference numerals shown in FIG. 1 have been employed as those for indicating the commonly used structural elements indicated in FIG. 4. Since the delay amount of the delay circuit 201 is variable, capabilities of the normal operation path 103 can be evaluated.

It should also be noted that the delay circuit 201 of the second embodiment mode may alternatively contain a fuse (not shown) which stores therein a delay value. In this alternative case, capabilities of the normal operation path 103 may be evaluated based upon the delay value stored in the fuse, so that capabilities of processes may be compared with each other and may be evaluated after the semiconductor device 200 has been assembled in packages. Alternatively, the external memory 151 may be provided within the semiconductor device 200 similar to the first embodiment mode.

### Third Embodiment Mode

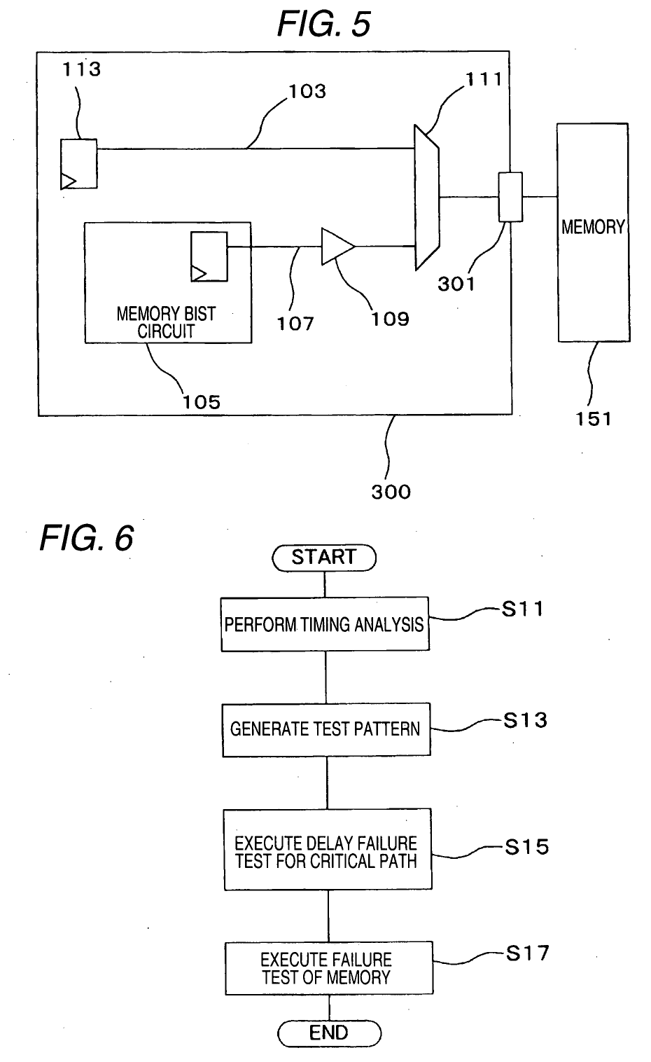

FIG. 5 is a block diagram for indicating a structure of a semiconductor device 300 according to a third embodiment mode of the present invention. The semiconductor device 300 of this third embodiment mode has the following different points from the semiconductor device 100 as described in the first embodiment mode. That is, in the third embodiment mode, a memory 151 is provided outside the semiconductor device 300, and an output terminal 301 of the semiconductor device 300 is provided on the output side of a selector 111. The output terminal 301 is to be connected to the externally provided memory 151. Other points than the above-described points are similar to those of the first embodiment mode, and the same reference numerals shown in FIG. 1 have been employed as those for indicating the commonly used structural elements indicated in FIG. 5. The output terminal 301 has a circuit (not shown) which switches current levels of signals outputted from the selector 111. Alternatively, the external memory 151 may be provided within the semiconductor device 300 similar to the first embodiment mode.

The semiconductor devices according to the present invention are useful as an LSI and the like, which are capable of performing the screening inspections in the higher efficiencies.

What is claimed is:

1. A semiconductor device having a self test function, comprising:
a failure detecting circuit for detecting a failure of a logic circuit by employing a test pattern;
a critical path defined up to said logic circuit;
a test path defined from said failure detecting circuit up to said logic circuit;
a delay circuit provided on the test path, to which a delay value equivalent to a delay value of said critical path is set; and
a selecting/outputting circuit for selecting any one of a signal inputted via the critical path and another signal inputted via the test path and for outputting the selected signal; wherein:
said selecting/outputting circuit outputs the signal entered via the critical path when said semiconductor device is operated under normal operation, and outputs the signal entered via said test path and said delay circuit when said semiconductor device is operated under self test operation.

2. The semiconductor device as claimed in claim 1 wherein said delay value of the critical path is obtained by a timing analysis.

3. The semiconductor device as claimed in claim 1 wherein the delay value set to said delay circuit is variable.

4. The semiconductor device as claimed in claim 3 wherein said delay circuit includes a storage unit for storing thereinto said set delay value.

5. The semiconductor device as claimed in claim 1, further comprising:
an output terminal for switching current levels of the signals outputted from said selecting/outputting unit.

6. The semiconductor device as claimed in claim 1 wherein said logic circuit is a memory.

7. The semiconductor device as claimed in claim 1, wherein said logic circuit is provided inside said semiconductor device.

8. The semiconductor device as claimed in claim 1 wherein said failure of said logic circuit detected by said failure detecting circuit contains a delay failure.
